(19) United States
(12) Patent Application Publication
(10) Pub. No.: US 2014/0159231 A1
(43) Pub. Date: Jun. 12, 2014

(54) SEMICONDUCTOR ASSEMBLY

(71) Applicant: Nils Magnus Lundberg, Hollviken (SE)

(72) Inventor: Nils Magnus Lundberg, Hollviken (SE)

(73) Assignee: SONY MOBILE COMMUNICATIONS AB, Lund (SE)

(21) Appl. No.: 13/637,140

(22) PCT Filed: Aug. 4, 2011
(86) PCT No.: PCT/IB11/53491

§ 371 Date: Sep. 25, 2012

(51) Int. Cl. H01L 23/498; H01L 21/50

(52) U.S. Cl. CPC H01L 23/49811; H01L 21/50
USPC 257/737; 438/121; 257/773

(57) ABSTRACT

A semiconductor assembly that may enhance dissipation of heat. The assembly includes a first die of a first material and defining a first passage. A second material, such as silicon carbide, diamond, or carbon nanotube, having a higher heat conductivity than the first material is disposed in the center of the first passage. An electronic component, which may be, for example, another die or a printed wiring board, is adjacent to the first die, is predominantly of a third material, and defines a first opening. A fourth material having a higher heat conductivity than the third material is disposed in the center of the first opening. The first opening is in alignment with the first passage, and may provide for heat transfer with a chimney effect between the materials of relatively high heat conductivity. A mold including a high heat conductivity material may also be provided.

### TECHNICAL FIELD

Embodiments described herein relate generally to integrated circuits and associated electronics, and more particularly to heat conductive features of vertically stacked dies, printed board assemblies, and other components.

### BACKGROUND

In three dimensional packaging, connected integrated circuits are made more compact by vertically stacking two or more dies with a high speed and substantially direct interface. The primary driver for vertically stacked dies is better signal performance, i.e., less parasitic as wire length is reduced. Micro ball connections that may be used with vertical die stacks instead of relatively long leads on the periphery of the chips may reduce elapsed time for communication of signals between components as wire lengths both internal to a die and between dies in a system may be shortened. In the case of CPU and dynamic random access memory (DRAM) dies, this effect is manifested in higher bandwidth such that there is faster communication between the CPU and DRAM dies. As a secondary driver for vertical stacking of dies, vertical die stacks are desirable to reduce the footprint and overall size of the integrated circuits. However, upper or outer vertical dies impede dissipation of heat from lower or inner dies or other components, and prevalent increased processor speeds may generate more heat than other types of processors. Concurrently, the sizes of dies in general have been reduced, which reduces the surface area available for dissipating heat. Accordingly, there is concern with respect to thermal impact in die stacking and in printed board assemblies.

For the foregoing reasons, there is a need for heat to be dissipated from die stacks and printed board assemblies.

### SUMMARY

In accordance with one embodiment, a semiconductor assembly is provided. The assembly includes a first die including a first material and defining a first passage therethrough having a first longitudinal axis. A second material is disposed in the first passage along the first longitudinal axis. An electronic component is mounted to the first die, and the majority of the electronic component includes a third material. The electronic component defines a first opening having a second longitudinal axis. A fourth material is disposed in the first opening along the second longitudinal axis. Connection material contacts both the first die and the electronic component at the first passage and the first opening. The second material has a higher thermal conductivity than the first material, and the fourth material has a higher thermal conductivity than the third material.

In some such embodiments, the first longitudinal axis is in substantial alignment with the second longitudinal axis. In some embodiments, the first passage is in alignment with the first opening.

In some embodiments, the electronic component includes a second die, and the second die has an active portion and a passive portion, and the first opening is defined in the passive portion. In some other embodiments, the first opening is a second passage extending entirely through the second die.

In some embodiments, the electronic component includes a printed wiring board. In some such embodiments, the first opening is a through hole via in the printed wiring board. In further embodiments, the semiconductor assembly further includes a second die on the opposite side of the printed wiring board from the first die. The second die includes a fifth material and defines a second opening having a third longitudinal axis. A connection material contacts both the electronic component and the second die at the first opening and the second opening. A sixth material is disposed along the third longitudinal axis, and the sixth material has a higher thermal conductivity than the fifth material. In some embodiments, the third longitudinal axis is in substantial alignment with the first and second longitudinal axes. In some embodiments, the first passage, first opening, and second opening are in alignment. In some embodiments, the sixth material includes silicon carbide, diamond, carbon nanotube, or combinations thereof

In other embodiments, the semiconductor assembly further includes a mold encapsulating at least one die, and the mold material has a higher thermal conductivity than the first material. In some embodiments, the mold material includes silicon carbide, diamond, carbon nanotube, or combinations thereof

In some embodiments, the second and fourth materials are the same material, and in some embodiments the second and fourth materials include silicon carbide, diamond, carbon nanotube, or combinations thereof

In some embodiments, the second material extends outward from the first die. In some embodiments, the first material includes silicon (Si), gallium arsenide (GaAs), indium phosphide (InP), or another III-IV semiconductor compound. In some embodiments, the third material includes silicon (Si), gallium arsenide (GaAs), indium phosphide (InP), or another III-IV semiconductor compound.

In some embodiments, the first die comprises a Micro Pillar Grid Array. In some embodiments, the connection material comprises a micro bump. In some such embodiments, the micro bump is formed from a copper (Cu) post and a tin (SN) cap.

In accordance with another embodiment, a mobile terminal is provided. The mobile terminal includes a housing and a semiconductor assembly disposed in the housing. Such a semiconductor assembly is provided in accordance with embodiments as described above.

In accordance with another embodiment, a method of making a semiconductor assembly is provided. The method includes providing a first die including a first material and forming a first passage through the first die, with the first passage having a first longitudinal axis. A second material is placed in the first passage along the first longitudinal axis. An electronic component, the majority of which comprises a third material, is provided. A first opening is formed in the electronic component, with the first opening having a second longitudinal axis. A fourth material is placed in the first opening along the second longitudinal axis. The first die is mounted to the electronic component with connection material contacting both the first die and the electronic component at the first passage and the first opening. The second material has a higher thermal conductivity than the first material, and the fourth material has a higher thermal conductivity than the third material.

In some embodiments, after mounting the first die to the electronic component the first longitudinal axis is in substantial alignment with the second longitudinal axis. In some embodiments, after mounting the first die to the electronic component the first passage is in alignment with the first opening.

In some embodiments, the electronic component includes a second die, and the second die has an active portion and a passive portion, and the first opening is defined in the passive portion. In some other embodiments, the first opening is a second passage entirely through the second die.

In some embodiments, the electronic component includes a printed wiring board. In some such embodiments, the first opening is a through hole via in the printed wiring board. In some such embodiments, the method further includes providing a second die comprising a fifth material and forming a second opening in the second die, with the second opening having a third longitudinal axis. The second die is mounted to the opposite side of the printed wiring board from the first die with a connection material contacting both the printed wiring board and the second die at the first opening and the second opening. A sixth material is placed in the second opening along the third longitudinal axis, and the sixth material has a higher thermal conductivity than the fifth material. In some embodiments, after mounting the second die to the printed wiring board the third longitudinal axis is in substantial alignment with the first and second longitudinal axes. In some embodiments, after mounting the second die to the electronic component the first passage, first opening, and second opening are in alignment. In some embodiments, the sixth material includes silicon carbide, diamond, carbon nanotube, or combinations thereof.

In some embodiments, the method further includes encapsulating at least one die in a mold, wherein the mold material has a higher thermal conductivity than the first material. In some such embodiments, the mold material includes silicon carbide, diamond, carbon nanotube, or combinations thereof

In some embodiments, the second and fourth materials are the same material, and in some embodiments the second and fourth materials include silicon carbide, diamond, carbon nanotube, or combinations thereof

In some embodiments, the second material extends outward from the first die. In some embodiments, the first material includes silicon (Si), gallium arsenide (GaAs), indium phosphide (InP), or another III-IV semiconductor compound. In some embodiments, the third material includes silicon (Si), gallium arsenide (GaAs), indium phosphide (InP), or another III-IV semiconductor compound.

In some embodiments, the first die comprises a Micro Pillar Grid Array. In some embodiments, the connection material comprises a micro bump. In some such embodiments, the micro bump is formed from a copper (Cu) post and a tin (SN) cap.

### BRIEF DESCRIPTION OF THE DRAWINGS

For a more complete understanding, reference should now be had to the embodiments shown in the accompanying drawings and described below. In the drawings:

FIG. 1 is a schematic section view of a first embodiment of a semiconductor assembly.

FIG. 2 is a schematic section view of a second embodiment of a semiconductor assembly.

FIG. 3 is a schematic section view of a third embodiment of a semiconductor assembly.

FIG. 4 is a schematic section view of a fourth embodiment of a semiconductor assembly.

FIG. 5 is a front view of an embodiment of a mobile device including a semiconductor assembly as shown in any one of FIGS. 1-4.

### DESCRIPTION

The embodiments of a semiconductor assembly described herein may be for use with conventional electronics. Moreover, it is understood that the overall construction of specific semiconductors and printed wiring boards is not critical. Accordingly, although exemplary embodiments will be described in detail herein with respect to heat dissipation from thermally enhanced die stacks and printed assembly boards, detailed explanations of the construction and functioning of the integrated circuits and boards are deemed unnecessary for understanding by one of ordinary skill in the art.

Certain terminology is used herein for convenience only and is not to be taken as a limitation. For example, words such as “upper,” “lower,” “left,” “right,” “horizontal,” “vertical,” “upward,” and “downward” merely describe the configuration shown in the figures. The components may be oriented in any direction and the terminology, therefore, should be understood as encompassing such variations unless specified otherwise.

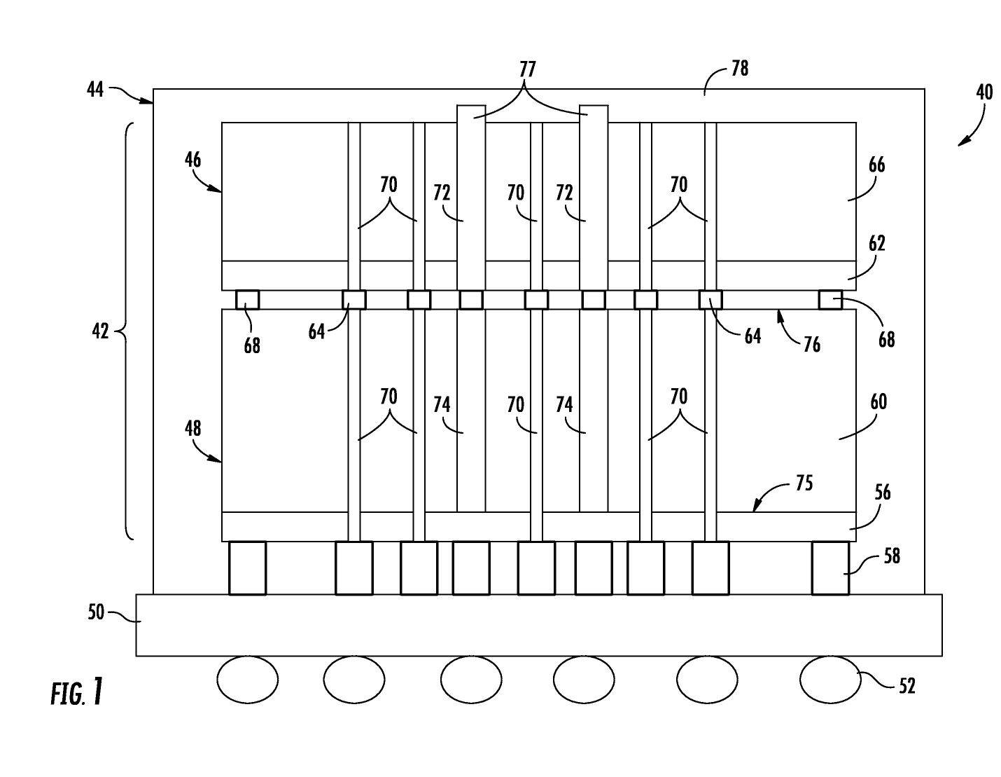

Referring now to the drawings, wherein like reference numerals designate corresponding or similar elements throughout the several views, a first embodiment of a semiconductor assembly 40 is shown in FIG. 1. A die stack 42 included in the semiconductor assembly 40 may be a die-die connection using a Micro Pillar Grid Array (MPGA) in package 44. The die stack 42 includes an upper die 46, a lower die 48, and a package substrate 50. The dies disclosed herein are semiconductors. Solder balls 52 are shown for connection to the bottom of the package substrate 50. The lower die 48 has an active portion 56 including an active surface proximate to and mounted to the package substrate 50, which may be done, for example, with copper (Cu) pillars 58. A passive portion 60 of the lower die 48 is on top of the active portion 56. The upper die 46 may be mounted to the lower die 46 with the active portion 62 of the upper die 46 proximate to the lower die 48 passive portion 60, using micro bumps 64. Such micro bumps 64 may be connection material such as, for example, a Cu post and a tin (Sn) cap (not shown).

A passive portion 66 of the upper die 46 is above the active portion 62. Additional mechanical connections with micro balls 68 may also be provided in various embodiments.

Passing through the entire thicknesses of each of the dies 46, 48 are Through-Silicon Vias (TSVs) 70, 72, which are passages completely through the dies 46, 48. TSVs may eliminate the edge wiring between dies, which generally is placed on the periphery of the dies. TSVs therefore potentially reduce wire length, with the TSVs allowing vertical connections through the body of the dies, resulting in less signal parasitic and a smaller footprint. With TSVs, no intermediate separating layer is required between dies. Because dies may be manufactured with materials other than silicon, a TSV may also be considered herein a through-semiconductor via.

Two types of TSVs are shown herein. The first type of TSV 70 is for data bus signals, power, and ground, of which five are shown in each die 46, 48 in FIG. 1. TSVs 70 in the upper die 46 may be aligned or at least substantially aligned with TSVs 70 in the lower die 48. This type of TSV 70 may also conduct heat. The second type of TSV 72 is only used in the upper die 46 in this embodiment, with two shown in FIG. 1, although they could also be used on a lower die in other embodiments. These

TSVs 72 are configured to provide thermal dissipation, and may be aligned or at least substantially aligned with a feature in the lower die 46 referred to herein as deep wells 74. The deep wells 74 are also openings for the purpose of heat dissipation. The deep wells 74, may extend, for example, from within a few microns of the upper side 75 of the active portion 56 (activated die material) of the lower die 48, to the upper side 76 of the lower die 46. The two deep wells 74 shown are also configured to provide thermal dissipation. The TSVs 70, 72 of the upper die 46 are connected to the TSVs 70 or deep wells 74, as applicable, of the lower die 48 with the micro bumps 64, such as Cu/Sn micro bumps.

In this semiconductor assembly 40 embodiment, the TSVs 72 and the deep wells 74 are relatively wide as compared to TSVs 70, which also provide heat dissipation, but to a lesser degree because of their reduced size. The TSVs 70, 72 and deep wells 74 are filled, after first being metal coated, with a relatively high heat conductivity material that has a higher heat conductivity than the die material or the metal coating, which may be, for example, copper. Such fill materials include, but are not limited to, silicon carbide (SiC), diamond, carbon nanotube (CNT), or combinations thereof. The deep wells start at or proximate to the active Si layer (i.e. a few microns away from processed layers of silicon) and extend to the backside of the die 48. Optionally, the material filling the TSVs 72 may include extensions 77 above the upper die 46, which may further enhance conduction of heat from the TSV 72 by providing surface area outside of the die 46.

The diameter of a TSV is typically from 1 to 30 μm. A deep well may have a diameter ranging from approximately 10 to 100 μm. With respect to deep wells and TSVs, a wider flow path for heat is superior for dissipation, so the dimensions of the flow path may be set by one of ordinary skill in the art depending on the severity of the local hot spot, or area where the greatest amount of heat is generated and/or accumulated as particular to a given die. Such a position may be, for example, where there is a relatively high degree of electrical activity. The position of a hot spot on a die could be calculated in advance or iterated for a specific package. The cross-sectional shape of the TSVs and deep wells may be circular or otherwise, and may, for example, take the shape of the applicable hot spot. Processed very-large-scale integration (VLSI) silicon is paid for by surface area, so a larger diameter deep well will be more expensive if it blocks other functionality by taking up otherwise usable surface area. Therefore, for cost reasons, deep wells may be designed just to “do the job,” and not be any larger than necessary.

Package 44 may also include a mold 78. Molds in general may be made of epoxy and ceramic fillers. An example of a ceramic that may be used is aluminum oxide. The mold 78 of the package 44 may have a high heat conductivity filler material that may be added to the epoxy. Such addition of filler may increase the heat conductivity of the mold 78. The filler may again be or include SiC, diamond, carbon nanotube, or combinations thereof. Alternatively, the mold 78 could be omitted entirely to have a bare die stack. In such embodiments, the extensions 77 of the material filling the TSVs would extend outward into the environment.

The dies 46, 48 in this embodiment of a semiconductor assembly 40 and the others described herein may be made using silicon (Si) and/or variants thereof. In some cases, for example, germanium (Ge) or Ge and carbon are added to Si to increase charge carrier mobility. Alternative materials may include, but not be limited to, gallium arsenide (GaAs), indium phosphide (InP), or other III-IV semiconductor compounds. Further, although Through-Silicon Vias are referred to herein as TSVs because of the prevalence of the use of silicon, in light of the fact that other materials may be used for the die, the term TSV is understood to apply to a like passage regardless of the die material. In the embodiment shown in FIG. 1, the upper die 46 may be, for example, a DRAM, and the lower die 48 may be a CPU die. However, various components may be used in such an arrangement, including but not limited to stacking of processor blocks.

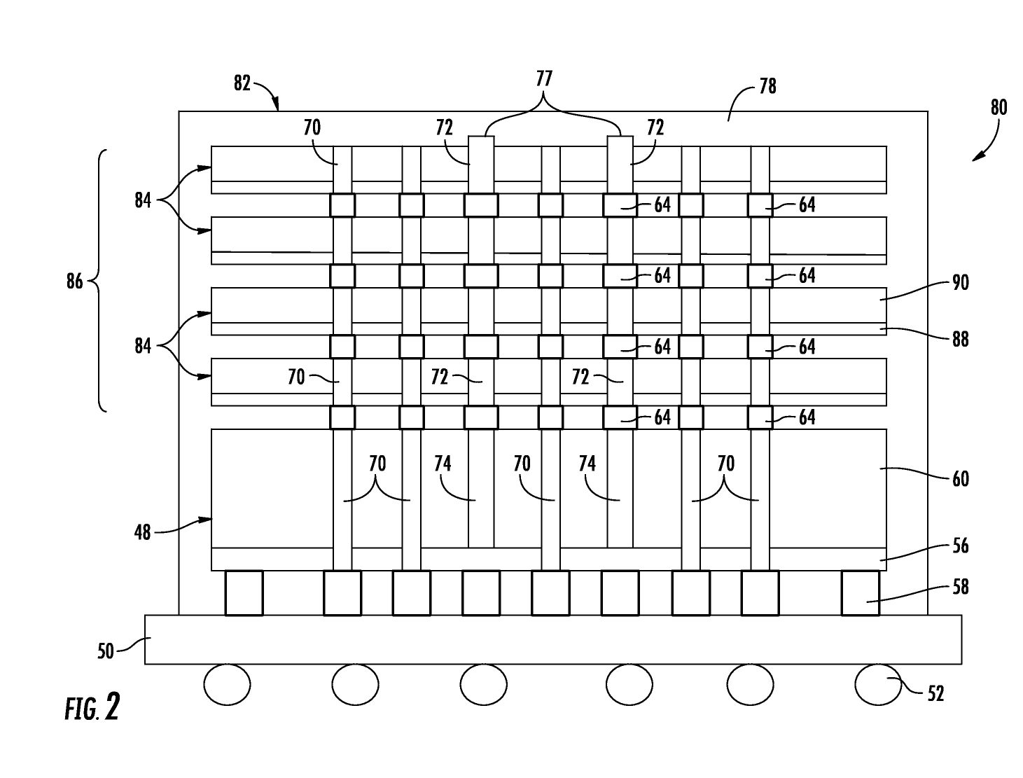

In a second embodiment of a semiconductor assembly 80 shown in FIG. 2, a package 82 includes a die stack of four DRAM dies 84 joined using MPGAs, which is a discrete and generally independently tested component known collectively as a memory cube 86 that replaces the single upper die 46 of FIG. 1, when the upper die 46 is a DRAM. The memory cube 86 as shown includes five relatively narrow TSVs 70 and two relatively wide TSVs 72, similar to the DRAM upper die 46 of FIG. 1. Further, each die 84 has an active portion 88 and a passive portion 90. Connections between the TSVs 70, 72 at the active portion 88 of a die 84 and the TSVs 70, 72 of the adjacent die 84 beneath the respective TSV may also be made with micro bumps 64, such as Cu/Sn micro bumps. Some or all of the dies 48, 84 in the package 82 may be overmolded, i.e., encapsulated within the mold 78, or alternatively may be a bare die stack.

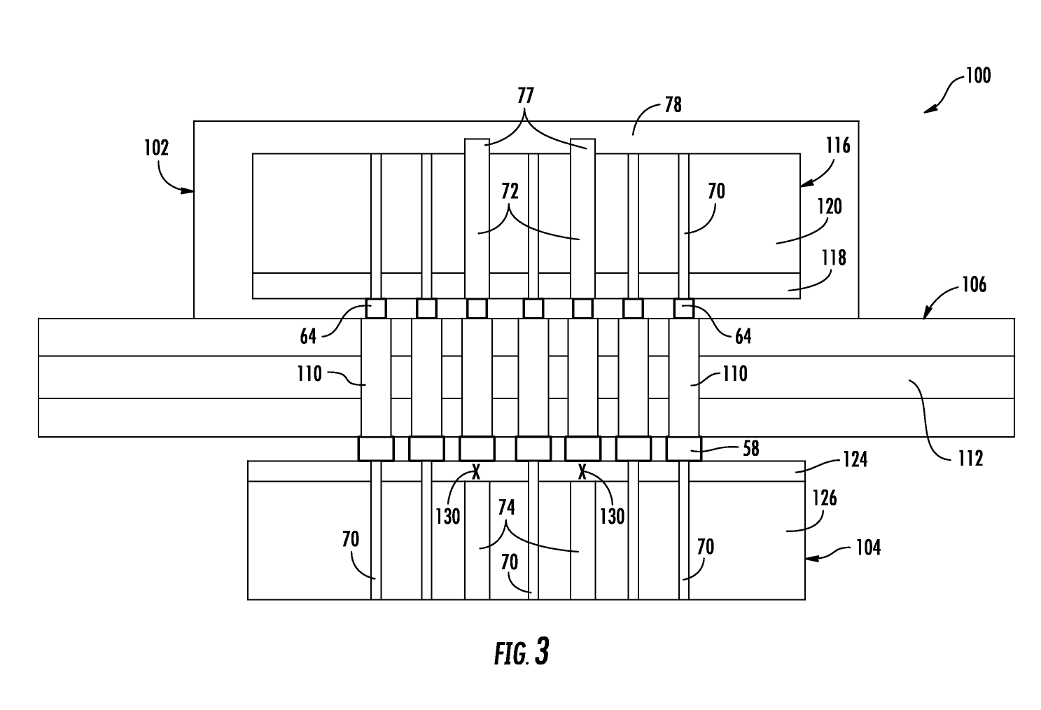

FIG. 3 shows a third embodiment of a semiconductor assembly 100 featuring a DRAM package 102, a CPU die 104, and a rigid interposer Printed Wiring Board (PWB) 106, such as a Mother-PWB. The PWB 106 as shown includes seven Through Hole Vias (THVs) 110 for conducting heat. THVs are conventionally filled with Cu. Like the previously described thermal TSVs 72 and deep wells 74, THVs 110 are filled, after first being metal coated, with a relatively high heat conductivity material that has a higher heat conductivity than the PWB 106 material or the metal coating. Such materials include, but are not limited to, silicon carbide (SiC), diamond, carbon nanotube (CNT), or combinations thereof. Alternatively, Cu-filled THVs 110 may be used in certain embodiments. The PWB 106 also includes core layers 112, which in some cases may be Ground (GWD) layers with slightly thicker Cu layers then in other parts of the PWB 106, and may therefore assist in heat dissipation as a heat sink. However, such a heat sink alone may be inadequate for the performance requirements of some semiconductor assemblies.

The DRAM package 102 includes a DRAM die 116 having an active portion 118 and a passive portion 120. The die 116 may be overmolded with a mold 78 including highly heat conductive filler, as previously described. CPU die 104 also has an active portion 124 and a passive portion 126, and as an alternative to the configuration shown, could be inside a package molding. The hot spots 130 are in this example substantially central to the active portion 124 and have influenced the placement of the wide TSVs 72 through the dies 104, 116.

In the semiconductor assembly 100 of FIG. 3, five relatively narrow TSVs 70 are once again included in each die 104, 116, two deep wells 74 are shown in the CPU die 104, and two relatively wide TSVs 72 are shown in the DRAM die 116, all for purposes including heat transfer. THVs 110 are aligned with the TSVs 70, 72, as applicable, in the DRAM die 116 and the CPU die 104. Accordingly, heat may flow along at least three paths. First, heat may flow from the active portion 124 of the CPU die 104 downward through the TSVs 70. Second, heat may flow from the active portion 124 of the CPU die 104 at the hot spots 130 downward through the deep wells 74. Third, heat may flow upward from the hot spots 130 or other locations in the active portion 124 through the Cu pillars 58, the THVs 110 in the PWB 106, the micro bumps 64, and then the TSVs 70, 72 to the mold 78, from which the heat may dissipate to the environment. The diameter of the THVs 110 may be, for example, approximately 400 to 500 μm if mechanically drilled in 1 mm thick PWB.

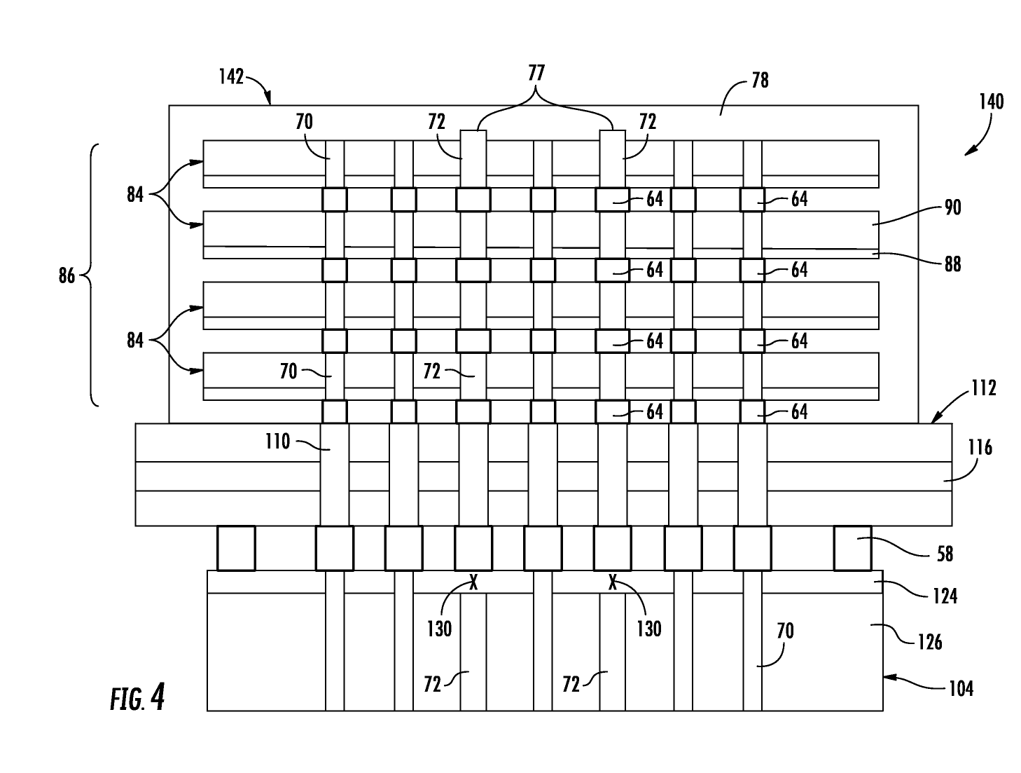

FIG. 4 shows a fourth embodiment of a semiconductor assembly 140 where the DRAM die 116 of FIG. 3 has been replaced with a memory cube 86 in package 142. The memory cube 86 may be constructed similarly to the memory cube 86 of FIG. 2. In this embodiment, heat may be conducted downward as in the embodiment of FIG. 3. Heat may also flow upward from the hot spots 130 or other locations along the active portion 124 of the CPU die 104 through the Cu pillars 58, the THVs 110, and then the plurality of the micro bumps 64 (such as Cu/Sn micro bumps) and TSVs 70, 72, and through the mold 78 to the environment.

The dies shown herein are exemplary, and are schematically depicted for the purposes of explanation. Accordingly, proportions and numbers of components, TSVs, THVs, deep wells, micro bumps, pillars, and other features may and are expected to vary from those shown in the figures. Although other connection arrangements may be used, the MPGAs shown are representative of those described in JEDEC (Solid State Technology Association) draft Publication 95 Design Guide 4.xx for Micro Pillar Grid Arrays (MPGA) (Jul. 1, 2011), the entire contents of which are incorporated by reference herein, with an outlined footprint of a wide I/O (input/output) interface. As set forth therein, an MPGA package has an array of metallic pillars on the underside of the package. The array of pillars provides the mechanical and electrical connection to the adjacent component, such as another die or a PWB. Wide I/O is made up of four channels of 128 bits each. For each individual channel, there is a matrix of 6×50 micro bumps with 40/50 μm pitch (vertical/horizontal). Vertical spacing between two channels is equal to two rows. Horizontal spacing between two channels is equal to six columns. Each array makes up a data channel from DRAM to a CPU or from DRAM to the next DRAM.

Silicon die thickness ranges from 700 μm down to 70 μm thickness depending on how much back grinding has been carried out. TSV-containing wafers are generally back grinded to less than 500 μm to get the aspect ratio in a working range. As referred to herein, the term “electronic component” refers to dies, PWBs, or the like.

The TSVs, deep wells, and THVs, which may be filled with relatively highly heat conductive material, may be aligned to provide a flow path for heat conduction that may create a chimney effect, thereby enhancing heat transfer. Where a mold is present, the highly heat conductive filler in the mold also may enhance heat transfer from the mold to the environment. With respect to the locations available for heat pathways, conventionally, TSVs are placed near or at the center of the die. The MPGA that provides the footprint for joining to TSV dies is approximately only 5 mm², so the TSVs can be located in many places; in general the TSVs can be located on any location of the die. Deep wells may be located any place on a die where heat needs to be removed. THVs may be located anywhere on the PWB. A typical Smartphone board, for example, already contains hundreds of drilled vias, and the addition of a limited number to dissipate heat may be considered generally inconsequential to functionality of a PWB.

TSVs and deep wells may be wet etched during Si fabrication. THVs are mechanically drilled in PWBs, generally at the facility where the PWB is manufactured. All holes may be coated with Cu, and in conventional products may be filled with either Cu, tungsten (W), or the like. TSVs and THVs are generally filled with such materials by chemical vapor deposition (CVD). CVD can also be used for the high heat conductivity fill materials disclosed herein, namely diamond, silicon carbide (SiC), and carbon nanotubes (CNT).

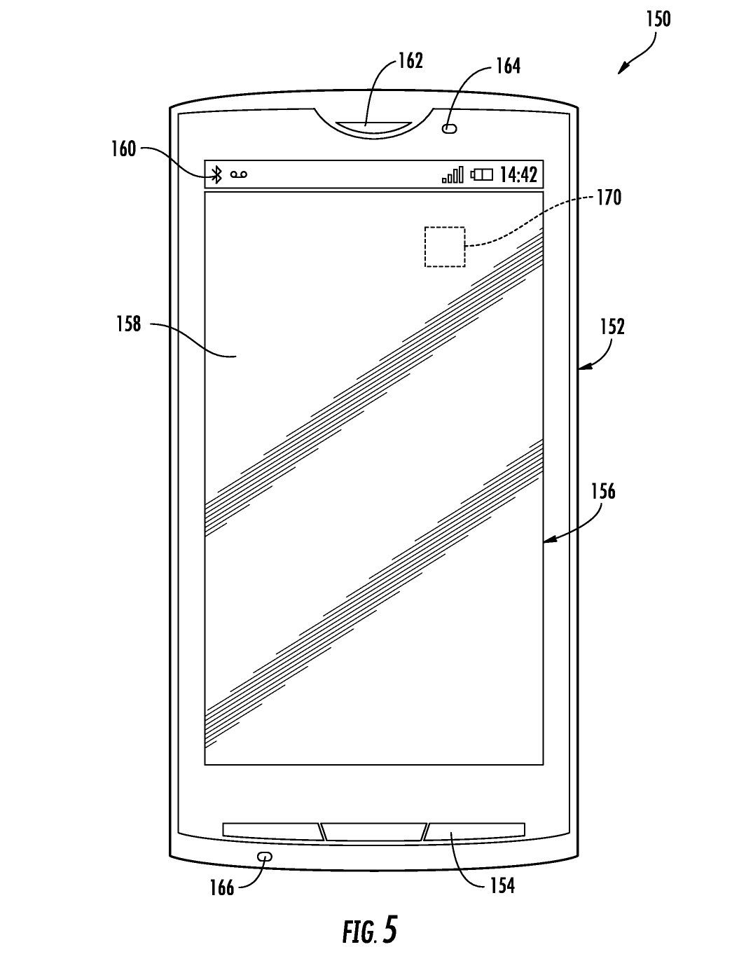

An embodiment of a mobile terminal, in this case a Smartphone, is shown in FIG. 5 and is generally designated at 150. Mobile terminal 150 includes a housing 152, operation control buttons 154, a screen 156, a display area 158 of the screen 156, a status bar area 160 of the screen 156, a speaker 162, a camera 164, and a microphone 166. Internal to the mobile terminal is a semiconductor assembly 170, which may be any one of the embodiments of semiconductor assemblies 40, 80, 100, 140 shown in FIGS. 1-4, or other embodiments that may feature TSVs, deep wells, THVs, or the like including relatively high heat conductive materials therein.

As used herein, the term “mobile terminal” may include devices including, but not limited to: a palmtop receiver or other appliance; a cellular radiotelephone with or without a multi-line display; a hand held phone; a Personal Communications System (PCS) terminal that may combine a cellular radiotelephone with data processing, facsimile and data communications capabilities; a PDA or Smartphone that can include a radiotelephone, pager, Internet/intranet access, Web browser, organizer, calendar and/or a global positioning system (GPS) receiver; a calculator; a handheld game or controller; a personal music playback system such as for CDs, minidisks, MP-3 files, memory sticks, or the like; a laptop computer; a Netbook; a tablet computer, for example, an iPad; and any handheld or portable device where small size is desired or necessary.

Although only a few exemplary embodiments have been shown and described in considerable detail herein, it should be understood by those skilled in the art that we do not intend to be limited to such embodiments since various modifications, omissions and additions may be made to the disclosed embodiments without materially departing from the novel teachings and advantages, particularly in light of the foregoing teachings. For example, the embodiments of die stacks described herein may be used in electronics other than mobile terminals. Accordingly, we intend to cover all such modifications, omission, additions and equivalents as may be included within the spirit and scope as defined by the following claims. In the claims, means-plus-function clauses are intended to cover the structures described herein as performing the recited function and not only structural equivalents but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

1. A semiconductor assembly comprising:
a first die comprising a first material and defining a first passage therethrough having a first longitudinal axis;
a second material disposed in the first passage along the first longitudinal axis;
an electronic component mounted to the first die, the majority of the electronic component comprising a third material and defining a first opening having a second longitudinal axis;
a fourth material disposed in the first opening along the second longitudinal axis; and
connection material contacting both the first die and the electronic component at the first passage and the first opening,
wherein the second material has a higher thermal conductivity than the first material, and wherein the fourth material has a higher thermal conductivity than the third material.

2. The semiconductor assembly according to claim 1, wherein the first longitudinal axis is in substantial alignment with the second longitudinal axis.

3. The semiconductor assembly according to claim 1, wherein the first passage is in alignment with the first opening.

4. The semiconductor assembly according to claim 1, wherein the electronic component comprises a second die.

5. The semiconductor assembly according to claim 4, wherein the second die has an active portion and a passive portion, and the first opening is defined in the passive portion.

6. The semiconductor assembly according to claim 5, wherein the first opening is a second passage entirely through the second die.

7. The semiconductor assembly according to claim 1, wherein the electronic component comprises a printed wiring board.

8. The semiconductor assembly according to claim 7, wherein the first opening is a through hole via in the printed wiring board.

9. The semiconductor assembly according to claim 8, further comprising:
a second die on the opposite side of the printed wiring board from the first die, the second die comprising a fifth material and defining a second opening having a third longitudinal axis;
a connection material contacting both the electronic component and the second die at the first opening and the second opening; and
a sixth material disposed along the third longitudinal axis,
wherein the sixth material has a higher thermal conductivity than the fifth material.

10. The semiconductor assembly according to claim 9, wherein the third longitudinal axis is in substantial alignment with the first and second longitudinal axes.

11. The semiconductor assembly according to claim 9, wherein the first passage, first opening, and second opening are in alignment.

12. The semiconductor assembly according to claim 9, wherein the sixth material comprises silicon carbide, diamond, carbon nanotube, or combinations thereof.

13. The semiconductor assembly according to claim 1 any of the preceding claims, further comprising a mold material encapsulating at least one die, wherein the mold material has a higher thermal conductivity than the first material, and wherein the mold material comprises silicon carbide, diamond, carbon nanotube, or combinations thereof.

14. (canceled)

15. The semiconductor assembly according to claim 1, wherein the second and fourth materials are the same material, and wherein the second and fourth materials comprise silicon carbide, diamond, carbon nanotube, or combinations thereof

16. (canceled)

17. The semiconductor assembly according to claim 1, wherein the second material extends outward from the first die.

18. The semiconductor assembly according to claim 1, wherein the first material comprises silicon (Si), gallium arsenide (GaAs), indium phosphide (InP), or another III-IV semiconductor compound, and wherein the third material comprises silicon (Si), gallium arsenide (GaAs), indium phosphide (InP), or another III-IV semiconductor compound.

19. (canceled)

20. The semiconductor assembly according to claim 1, wherein the first die comprises a Micro Pillar Grid Array.

21. The semiconductor assembly according to claim 1, wherein the connection material comprises a micro bump, and wherein the micro bump is formed from a copper (Cu) post and a tin (SN) cap.

22. (canceled)

23. A mobile terminal comprising:
a housing; and
a semiconductor assembly disposed in the housing, comprising:
a first die comprising a first material and defining a first passage therethrough having a first longitudinal axis;
a second material disposed in the first passage along the first longitudinal axis;
an electronic component mounted to the first die, the majority of the electronic component comprising a third material and defining a first opening having a second longitudinal axis;
a fourth material disposed in the first opening along the second longitudinal axis; and
connection material contacting both the first die and the electronic component at the first passage and the first opening,
wherein the second material has a higher thermal conductivity than the first material, and wherein the fourth material has a higher thermal conductivity than the third material.

24-44. (canceled)

45. A method of making a semiconductor assembly, the method comprising:
providing a first die comprising a first material;
forming a first passage through the first die having a first longitudinal axis;
placing a second material in the first passage along the first longitudinal axis;
providing an electronic component, the majority of which comprises a third material;
forming a first opening in the electronic component having a second longitudinal axis;
placing a fourth material in the first opening along the second longitudinal axis; and
mounting the first die to the electronic component with connection material contacting both the first die and the electronic component at the first passage and the first opening,
wherein the second material has a higher thermal conductivity than the first material, and wherein the fourth material has a higher thermal conductivity than the third material.

46-66. (canceled)
